(19) United States
(12) Patent Application Publication
(10) Pub. No.: US 2026/0150719 A1
(43) Pub. Date: May 28, 2026

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventor: Yuto KIYAMA, Tokyo (JP)

(73) Assignee: Mitsubishi Electric Corporation, Tokyo (JP)

(21) Appl. No.: 19/310,247

(22) Filed: Aug. 26, 2025

(30) Foreign Application Priority Data
Nov. 25, 2024 (JP) 2024-204450

(51) Int. Cl. H01L 23/495; H01L 21/48; H01L 21/56; H01L 23/00; H01L 25/16; H10D 80/30

(52) U.S. Cl. CPC H10W 70/481; H10W 70/041; H10W 74/016; H10W 90/00; H10D 80/30; H10W 70/417; H10W 72/5363; H10W 72/884; H10W 90/736; H10W 90/753; H10W 90/756

(57) ABSTRACT

A semiconductor device includes a first semiconductor chip, a second semiconductor chip, a wire connecting the first semiconductor chip and second semiconductor chip, a first frame portion on which the first semiconductor chip is mounted, a second frame portion positioned above the first frame portion and apart in a left-right direction from the first frame portion and on which the second semiconductor chip is mounted, and a sealing member, wherein a recess recessed downward is formed on an upper surface of the second frame portion, the recess is positioned above the first frame portion, and the second semiconductor chip is fixed in the recess.

### BACKGROUND

### Field

The disclosure relates to a semiconductor device and a method for manufacturing a semiconductor device.

### Background

JP 2001-250911 A discloses an example of a resin-sealed type power semiconductor device. In the semiconductor device, a power semiconductor chip is provided on the upper surface of a die pad, and a thick film substrate is joined via a bonding layer on multiple support inner leads among the inner leads positioned above the die pad. On the upper surface of the thick film substrate, all the control circuit patterns for the power semiconductor chip are formed as thick film patterns, and semiconductor chips for the control circuit are mounted on the thick film patterns via solder. The electrodes of the power semiconductor chip and the thick film patterns are electrically connected by wires. Furthermore, by having the support inner lead positioned above the die pad, the insulation distance between the power semiconductor chip provided in the die pad and the semiconductor chip on the support inner lead is maintained. Therefore, the wire has a length necessary to maintain the insulation distance.

The resin-sealed type power semiconductor device disclosed in JP 2001-250911 A is manufactured by, for example, transfer molding. In this molding process, a sealing member such as resin is injected between the two semiconductor chips. On the other hand, an elongated wire with a length required to maintain an insulating distance is provided between the two semiconductor chips. Therefore, stress may act on the wire due to the sealing member injected between the semiconductor chips during molding, potentially causing the wire to deform.

### SUMMARY

This disclosure has been made to solve the aforementioned issue and aims to provide a semiconductor device and method for manufacturing the semiconductor device, which can suppress wire deformation connecting the semiconductor chips while maintaining the insulation distance between the semiconductor chips in the semiconductor device sealed with the sealing member.

The features and advantages of the present disclosure may be summarized as follows.

According to an aspect of the present disclosure, a semiconductor device includes a first semiconductor chip, a second semiconductor chip connected to the first semiconductor chip, a wire connecting the first semiconductor chip and second semiconductor chip, a first frame portion on which the first semiconductor chip is mounted, a second frame portion positioned above the first frame portion and apart in a left-right direction from the first frame portion and on which the second semiconductor chip is mounted, and a sealing member sealing the first semiconductor chip, the second semiconductor chip, the first frame portion, the second frame portion, and the wire, wherein a recess recessed downward is formed on an upper surface of the second frame portion, the recess is positioned above the first frame portion, and the second semiconductor chip is fixed in the recess.

According to an aspect of the present disclosure, a method for manufacturing a semiconductor device includes preparing a first frame portion and a second frame portion positioned above the first frame portion and apart in a left-right direction from the first frame portion, mounting a first semiconductor chip on the first frame portion and a second semiconductor chip on the second frame portion, connecting the first semiconductor chip and the second semiconductor chip with a wire, and sealing the first semiconductor chip, the second semiconductor chip, the first frame portion, the second frame portion, and the wire with a sealing member, wherein in the preparation, a first mold having a molding recess, a second mold arranged opposite the molding recess and movable toward and away from the first mold, having a molding protrusion corresponding to the molding recess, and an original plate for the second frame potion are prepared, the original plate is placed in an area of the first mold including the molding recess, the second mold advances toward the first mold and punches out the original plate to form the second frame potion, and a recess is formed in the formed second frame potion that is recessed downward and located above the first frame portion, and in the mounting, the second semiconductor chip is fixed in the recess.

Other and further objects, features and advantages of the disclosure will appear more fully from the following description.

### BRIEF DESCRIPTION OF DRAWINGS

FIG. 1 is a perspective view showing the semiconductor device according to Embodiment 1.

FIG. 2 is a sectional view showing the semiconductor device according to Embodiment 1.

FIG. 3 is a perspective view showing the primary components within the semiconductor device according to Embodiment 1.

FIG. 4 is a flowchart of the method for manufacturing the semiconductor device according to Embodiment 1.

FIGS. 5 and 6 are perspective views showing the process for manufacturing the lead frame of the semiconductor device according to Embodiment 1.

FIG. 7 is a perspective view showing the primary components within the semiconductor device according to Embodiment 2.

FIG. 8 is a front view of the recess in the second frame portion of the semiconductor device according to Embodiment 2.

FIG. 9 is a plan view of the recess in the second frame portion of the semiconductor device according to Embodiment 2.

FIG. 10 is a perspective view showing the process for manufacturing the lead frame of the semiconductor device according to Embodiment 2.

FIG. 11 is a perspective view showing the primary components within the semiconductor device according to Embodiment 3.

FIG. 12 is a front view of the recess in the second frame portion of the semiconductor device according to Embodiment 3.

FIG. 13 is a plan view of the recess in the second frame portion of the semiconductor device according to Embodiment 4.

FIG. 14 is a perspective view showing the process for manufacturing the lead frame of the semiconductor device according to Embodiment 3.

FIG. 15 is a perspective view showing the primary components within the semiconductor device according to Embodiment 4.

FIG. 16 is a sectional view showing the semiconductor device according to Embodiment 4.

FIG. 17 is a front view of the recess in the second frame portion of the semiconductor device according to Embodiment 4.

FIG. 18 is a perspective view showing the process for manufacturing the lead frame of the semiconductor device according to Embodiment 4.

FIG. 19 is a sectional view showing the process for manufacturing the lead frame of the semiconductor device according to Embodiment 4.

FIG. 20 is a sectional view showing a modification example of Embodiment 1.

### DESCRIPTION OF EMBODIMENTS

The terms “upper,” “lower,” etc., indicating direction used in the following description reflect the relative position in the semiconductor device, and are not meant to limit the orientation during manufacturing or usage of the semiconductor device.

### Embodiment 1

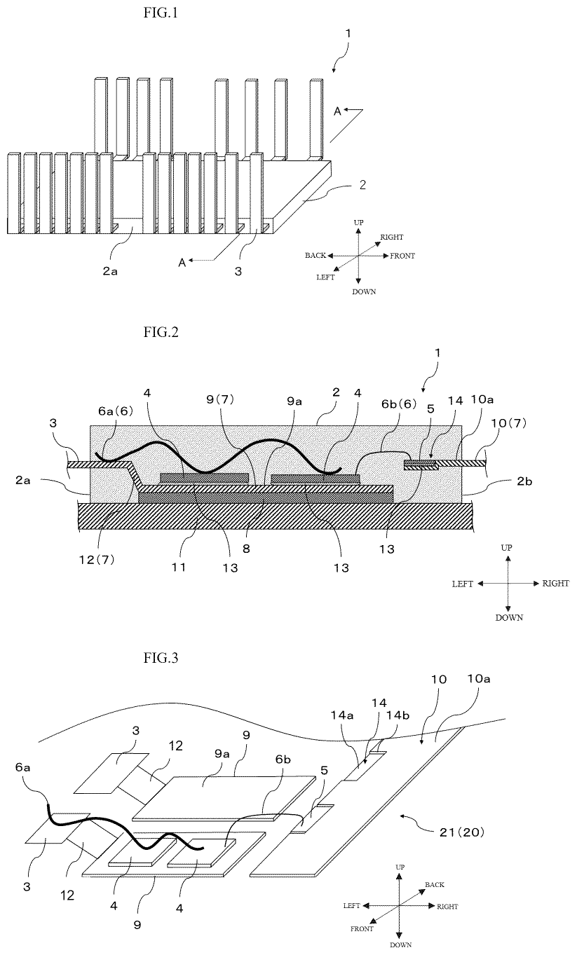

Embodiment 1 of this disclosure will be explained below with reference to the drawings. FIG. 1 is a perspective view showing the semiconductor device 1 according to Embodiment 1. FIG. 2 is a sectional view along line A-A of FIG. 1, showing the cross-section of semiconductor device 1.

As shown in FIG. 1, the semiconductor device 1 comprises an sealing member 2 and several external terminals 3 exposed from the sealing member 2. The sealing member 2 is formed in the shape of a rectangular plate made of resin. The external terminals 3 are arranged in a front-to-back direction on the left side 2a and right side 2b of the sealing member 2. Each external terminal 3 extends outwards in the left-right direction from the side surfaces 2a, 2b of the sealing member 2, and then bends at approximately a right angle to extend upwards. The external terminal 3 is mounted on a control board that has a control circuit (not illustrated) and is electrically connected to the exterior of semiconductor device 1. As shown in FIG. 2, inside the sealing member 2, a first semiconductor chip 4, a second semiconductor chip 5, a wire 6, a lead frame 7, and an insulating sheet 8 are provided. It should be noted that FIG. 2 does not show the bent section above the external terminal 3.

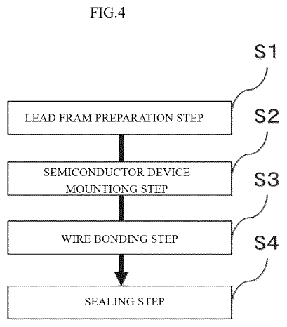

FIG. 3 is a perspective view showing the primary components within the semiconductor device 1, including the first semiconductor chip 4, the second semiconductor chip 5, the wire 6, and the lead frame 7.

The first semiconductor chip 4 is made of Si and is a so-called power semiconductor chip that controls power. The first semiconductor chip 4 is, for example, an IGBT (Insulated Gate Bipolar Transistor), MOSFET (Metal-Oxide-Semiconductor Field-Effect Transistor), or FWD (FreeWheeling Diode). One side of the first semiconductor chip 4 is, for example, about 3 mm to 13 mm. The first semiconductor chip 4 is not limited to Si, it may also be a wide bandgap semiconductor such as SiC or GaN. The first semiconductor chip 4 is mounted on the first frame portion 9 of the lead frame 7.

The second semiconductor chip 5 is an IC (Integrated Circuit) that controls the first semiconductor chip 4, such as an HVIC (High Side Gate Driver) and an LVIC (Low Side Gate Driver). The second semiconductor chip 5 is mounted on the second frame portion 10 of the lead frame 7 and is electrically connected to the first semiconductor chip 4 by wire 6. The size of the second semiconductor chip 5 is smaller than, for example, an IGBT or MOSFET, and due to the small control current value, it is wire-bonded using the ball bonding method.

The wire 6 may be made of any metal, for example, pure Al or a conductive metal primarily composed of Al. Wire 6 includes a wire 6a connecting the first semiconductor chip 4 and the lead frame 7, and a wire 6b connecting the first semiconductor chip 4 and the second semiconductor chip 5. Wire 6a connects the collector electrode on the upper surface of the IGBT to the lead frame 7 in cases where the first semiconductor chip 4 is an IGBT. Wire 6b connects the gate electrode of the IGBT to the second semiconductor chip 5 in cases where the first semiconductor chip 4 is an IGBT. Wire 6b is thinner compared to wire 6a, with wire 6a having a diameter of, for instance, 200μ to 400 μm and wire 6b having a diameter of, for instance, 30 μm to 60 μm.

A lead frame 7 is equipped with a first semiconductor chip 4 and a second semiconductor chip 5 connected to the first semiconductor chip 4. Through the wiring connection of wire 6b, a circuit is formed within the semiconductor device 1. The thickness of lead frame 7 is, for example, about 0.3 to 1.0 mm. Lead frame 7 and external terminal 3 are formed from a single sheet of metal. The single sheet of metal has been cut, formed, etc., using a mold from, resulting in the lead frame 7 and external terminal 3 with a stepped structure. The materials for lead frame 7 and external terminal 3 are conductive metal materials mainly composed of Cu, or in addition to conductivity, it is even better if thermal conductivity is present. For example, alloys such as Cu—Mo may be used.

The lead frame 7 includes a first frame portion 9 where the first semiconductor chip 4 is provided, and a second frame portion 10 positioned above the first frame portion 9 and apart in a left-right direction (the right in this embodiment) from the first frame portion 9 and where the second semiconductor chip 5 is mounted,

Inside the sealing member 2, multiple first frame portions 9 are arranged, and these first frame portions 9 are lined up in the front-back direction at the center section in the left-right direction inside the sealing member 2. The first frame portion 9 is the die pad portion of the lead frame 7. An insulation sheet 8, which electrically insulates, is provided on the underside of the first frame portion 9. The insulation sheet 8 may be arranged sandwiched between the upper first frame portion 9 and the lower heat sink 11. In that case, part of the heat sink 11 is exposed from the sealing member 2. It is also possible to use an insulating substrate for the first frame portion 9. In this case, the second frame portion 10 may be a metal terminal serving as an alternative to the lead frame 7, and the second semiconductor chip 5 may be mounted on this metal terminal.

The first frame portion 9 is connected to the external terminal 3 via the connecting part 12. The first frame portion 9 is a rectangular plate member that is long in the left-right direction and is positioned in the central part in the left-right direction of the sealing member 2, below the external terminal 3. Moreover, the first frame portion 9 is arranged such that its thickness direction aligns with the up-down direction. The first semiconductor chip 4 is fixed to the upper surface 9a of the first frame portion 9 via a bonding material 13. The material of bonding material 13 is, for example, a solder material mainly composed of Sn. Furthermore, bonding material 13 can be composed of a material with good heat dissipation properties relative to the first semiconductor chip 4, such as glue mainly composed of Ag, or a sintered material. The connecting part 12 is a rectangular plate member with a narrower front-to-back width than that of the first frame portion 9 and the external terminal 3. The connection section 12 inclines downward to the right from the right end of the external terminal 3 and is connected to the first frame portion 9.

The second frame portion 10 is a rectangular plate member that is long in the front-back direction, and it is positioned above and to the right of the first frame portion 9. Additionally, the second frame portion 10 is arranged such that its thickness direction aligns with the up-down direction. The second frame portion 10 is longer in the front-back direction than the first frame portion 9. On the upper surface 10a of the second frame portion 10, multiple second semiconductor chips 5 are arranged in a spaced manner in the front-back direction.

The region of the upper surface 10a of the second frame portion 10, excluding the part where the second semiconductor chips 5 are installed, forms a flat surface. On the other hand, the areas for installing the second semiconductor chips 5 on the upper surface 10a of the second frame portion 10 are provided at intervals in the front-back direction along the edge on the left side of the upper surface 10a, i.e., along the edge on the first frame portion 9 side. A recess 14 that indents downward is formed in the area where the second semiconductor chip 5 is installed. In FIG. 3, FIG. 3 shows the first two first frame portions 9 from the front out of the multiple first frame portions 9 lined up in the front-back direction, and further illustrates a part of the second frame portion 10 including the second recess 14 from the front. In FIG. 3, among the multiple first semiconductor chips 4 and multiple second semiconductor chips 5, only the foremost first semiconductor chip 4 and the foremost second semiconductor chip 5 are shown, and the illustration of the other chips is omitted.

The distance between adjacent recesses 14 in the front-to-back direction is approximately the same as the distance between adjacent first frame portions 9. Each recess 14 has a rectangular shape slightly larger than the second semiconductor chip 5 in plan view. Each recess 14 is open on the left side, that is, the side of the first frame portion 9. Each recess 14 has a bottom part 14a that is a longitudinal rectangular shape in the front-back direction, and a side part 14b rising upwards from two edges extending in the left-right direction of the bottom part 14a and one edge extending in the front-back direction on the right side (i.e., the opposite side to the first frame portion 9). The depth of each recess 14 is preferably at least 10% of the thickness of the lead frame 7. Moreover, the bottom surface 14a is positioned above the first frame portion 9, and further above the first semiconductor chip 4 mounted on the upper surface 9a of the first frame portion 9. The second semiconductor chip 5 is entirely housed within the recess 14, and the upper surface of the second semiconductor chip 5 is at the same height or lower than areas of the upper surface 10a of the second frame portion 10 that are outside the recess 14. The second semiconductor chip 5 is fixed to the recess 14 via the bonding material 13 in a state where its left end is aligned with the open edge (left end) of the recess 14. Additionally, the second semiconductor chip 5 may be fixed such that a portion of the second semiconductor chip 5 protrudes to the left of the recess 14, that is, protrudes toward the first frame portion 9 side from the recess 14.

In the following, the method for manufacturing the semiconductor device 1 will be explained. FIG. 4 is a flowchart of the method for manufacturing the semiconductor device 1. First, the original plate 15 of the lead frame 7 is processed to prepare the lead frame 7 having the first frame portion 9 and the second frame portion provided at a position above and to the right of the first frame portion 9 (Step S1). The first semiconductor chip 4 is mounted on the first frame portion 9 of the prepared lead frame 7, and the second semiconductor chip 5 is mounted on the second frame portion 10 (Step S2). The first semiconductor chip 4 and the second semiconductor chip 5, which are mounted, are connected by wire bonding (Step S3). These first semiconductor chip 4, second semiconductor chip 5, the first frame portion 9 and the second frame portion 10 of the lead frame 7, as well as the wire 6, are sealed with the sealing member (Step S4).

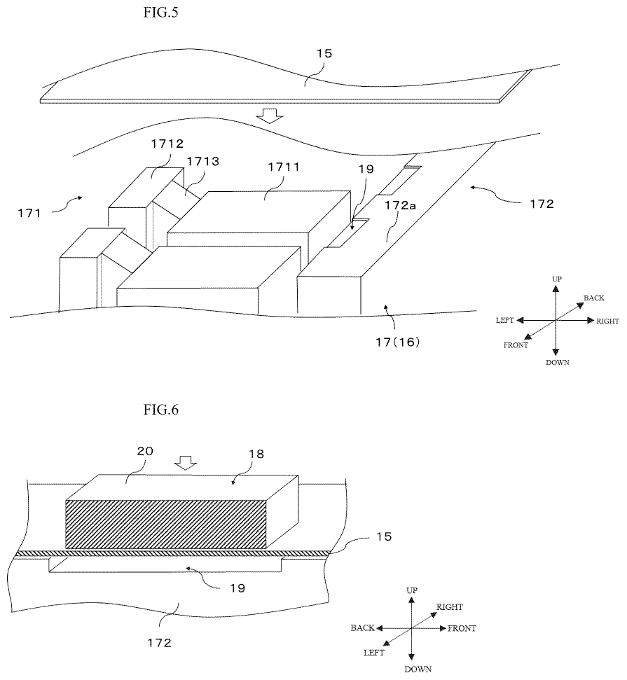

FIGS. 5 and 6 are perspective views showing a part of the process for manufacturing the lead frame 7 of the semiconductor device 1 according to Embodiment 1. FIG. 5 illustrates the process of punching the original plate 15 with the mold 16 in the step of preparing the lead frame 7. FIG. 6 is a perspective view showing the forming process of the recess 14.

In the above lead frame preparation step (Step S1), firstly, the original plate 15 and the mold 16 are prepared. The mold 16 is a die that performs punching and bending of the original plate 15. The mold 16 consists of a first mold 17 on which the original plate 15 is placed, and a second mold 18 arranged opposite to the first mold 17 to move toward and away from the first mold. FIG. 5 is a perspective view showing the state where the original plate 15 is placed on the mold 16. In addition, the original plate 15 is, for example, a copper plate.

The first mold 17 includes a first frame portion-side receiving mold 171 corresponding to the first frame portion 9, the external terminal 3, and the connecting part 12, and a second frame portion-side receiving mold 172 corresponding to the second frame portion 10. The first frame portion-side receiving mold 171 includes a cuboidally shaped first frame portion corresponding oart 1711 with a rectangular upper surface that corresponds to the first frame portion 9, a cuboidally shaped external terminal corresponding part 1712 with a rectangular upper surface that corresponds to the external terminal 3, and a rectangular connection part corresponding part 1713 with a slope that inclines downward to the right, corresponding to the connection part. The second frame portion-side receiving mold 172 is provided in a position that is above and to the right of the first frame portion-side receiving mold 171. The upper surface 172a of the second frame portion-side receiving mold 172 is in the form of an elongated rectangle in the front-back direction. In the part of this upper surface 172a corresponding to the mounting location of the second semiconductor chip 5, there is a downwardly recessed molding recess 19 for forming the recess 14. A number of molding recesses 19 are arranged in the front-back direction along the left edge of the upper surface 172a of the second frame portion-side receiving mold 172. The molding recesses 19 have a larger size than the second semiconductor chip 5 when viewed in plan. The depth of the molding recesses 19 is preferably at least 10% of the thickness of the lead frame 7.

The second mold 18 is a convex type that punches out the original plate 15 placed on the first mold 17 along the peripheral edges of the first frame portion-side receiving mold 171 and the second frame portion-side receiving mold 172 of the first mold 17, and bends the original plate 15 to conform to the shape along the upper surfaces of these receiving molds 171 and 172. In the position corresponding to the molded recess 19 of the second mold 18, a molding protrusion 20 for forming the recess 14 protrudes downward. The molded protrusion 20 is provided in multiple numbers in the front-back direction so as to correspond to the molded recess 19. In a plan view, the molded protrusion 20 is larger than the second semiconductor chip 5 but smaller than the molded recess 19.

In the lead frame preparation process mentioned above (Step S1), a original plate 15 with a larger surface area than the first mold 17 is placed on the first mold 17. A second mold 18 is advanced downward from above the original plate 15 to punch out the original plate 15, thereby forming the lead frame 7. In the molded second frame portion 10, a recess 14, positioned above the first frame portion 9, opens to the left towards the first frame portion 9, and indents downward, is formed.

In the aforementioned semiconductor device mounting step (Step S2), two first semiconductor chips 4 are mounted side by side in the left-right direction on the first frame portion 9, while one second semiconductor chip 5 is mounted in the recess 14 of the second frame portion 10. By mounting the second semiconductor chip 5 in the recess 14, the risk of misalignment of the second semiconductor chip 5 is reduced. The second semiconductor chip 5 is fixed in the recess 14 with its left end positioned at the open edge of the recess 14, i.e., the left end of the recess 14.

In the mentioned connection process (step S3), the first semiconductor chip 4 and the second semiconductor chip 5 are connected via a wire 6b. The second semiconductor chip 5 is fixed in the recess 14 that is recessed downward from the second frame portion 10 and is positioned along the open edge of the recess 14, thereby reducing the physical distance in both the up-down direction and the left-right direction between it and the first semiconductor chip 4. As a result, the length of the wire 6b can be shortened.

In the above sealing process (Step S4), a lead frame 7 in which an insulating sheet 8 is provided on the lower side of the first frame portion 9, the first semiconductor chip 4 and the second semiconductor chip 5 are mounted, and further the first semiconductor chip 4 and the second semiconductor chip 5 are connected with wire 6b is placed inside a cavity for transfer molding (not shown), and resin, which is the sealing member, is injected. At this time, although the stress of the sealing member acts on the wire 6b, since the length of the wire 6b is shortened, the deformation of the wire 6b is suppressed.

As described above, the first frame portion 9, to which the first semiconductor chip 4 is fixed, and the second frame portion 10, to which the second semiconductor chip 5 is fixed, are spaced apart in the up-down direction and the left-right direction. On the other hand, the second semiconductor chip 5 is provided on the upper surface 10a of the second frame portion 10, and is fixed in a recess 14 which is positioned above the first frame portion 9.

This allows the physical distance in the up-down direction between the first semiconductor chip 4 and the second semiconductor chip 5 to be shortened while maintaining the insulation distance between them. Therefore, it is possible to shorten the length of wire 6b connecting the first semiconductor chip 4 and the second semiconductor chip 5, reducing the stress applied to wire 6b during molding, and suppressing deformation of wire 6b. Furthermore, by fixing the second semiconductor chip 5 in the recess 14, the position of the second semiconductor chip 5 is stabilized, suppressing positional deviation when mounting the second semiconductor chip 5.

Additionally, the recess 14 is provided at the left end of the upper surface 10a of the second frame portion 10 and is open to the left. The left end of the second semiconductor chip 5 is secured so as to align with the open edge of the recess 14.

As a result, the physical distance in the left-right direction between the first semiconductor chip 4 and the second semiconductor chip 5 can be reduced. Accordingly, it becomes possible to further shorten the length of the wire 6b connecting the first semiconductor chip 4 and the second semiconductor chip 5.

### Embodiment 2

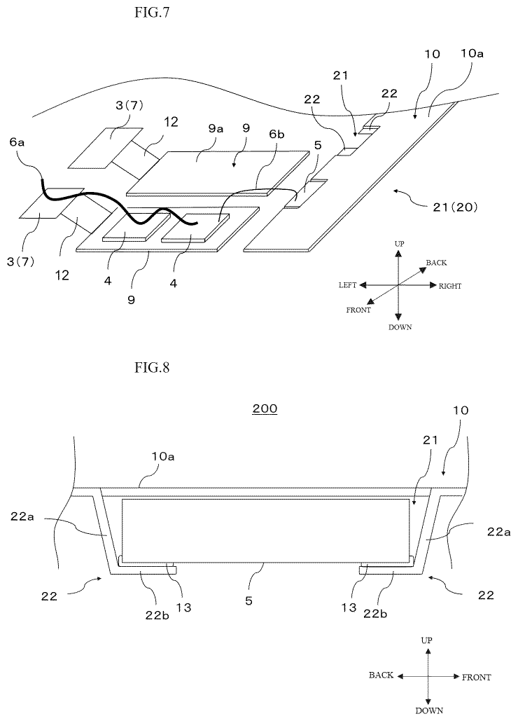

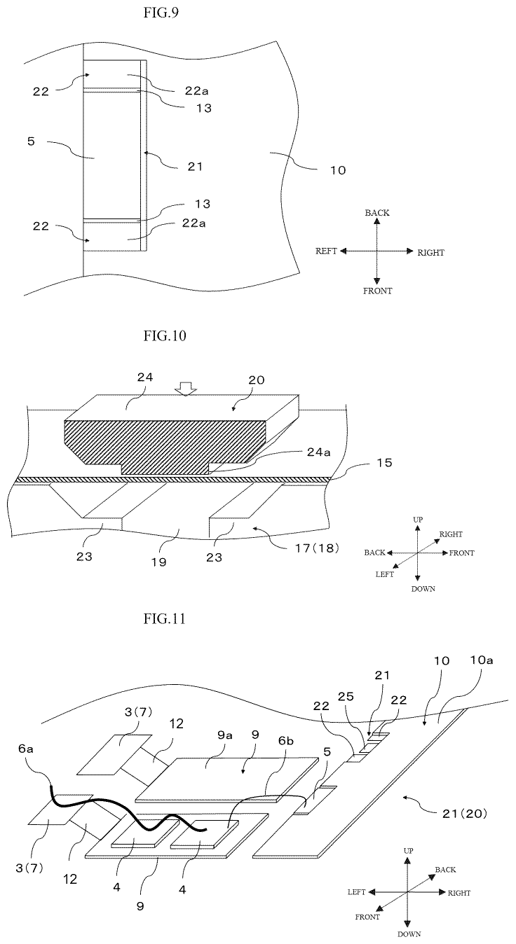

FIG. 7 is a perspective view showing the main part within the semiconductor device 200 according to Embodiment 2. FIG. 8 is a front view of the recess 21 in the second frame portion 10 of the semiconductor device 200 according to Embodiment 2. FIG. 9 is a plan view of the recess 21 in the second frame portion 10 of the semiconductor device 200 according to Embodiment 2. FIG. 10 is a perspective view showing the process for manufacturing the lead frame 7 of the semiconductor device 200 according to Embodiment 2. In the semiconductor device 200 related to Embodiment 2, components that are identical or similar to the semiconductor device 1 related to Embodiment 1 are indicated with identical reference numerals, and the focus will be on describing points of difference from Embodiment 1.

As shown in FIGS. 7, 8, and 9, a pair of support portions 22, spaced apart from one another in the front-to-back direction, are provided in the recess 21. The pair of support portions 22 are respectively provided at the front and back end portions of the recess 21. Each support portion 22 is formed by bending a rectangular plate section. Each support portion 22 has a side surface 22a inclined downward toward the inside in the front-back direction from the front or back end of the recess 21, and a bottom surface 22b extending from the lower end of the side surface 22a toward the inside in the front-back direction. Therefore, the side part 22a inclines upward as it moves away from the bottom part 22b. Also, the bottom parts 22b of the pair of support portions 22 are spaced apart from each other. The side parts 22a of the pair of support portions 22 are not connected to other parts of the second frame portion 10 on both the left and right sides. Therefore, the pair of support portions 22 are open on both the left and right sides. The front-to-back distance between the lower ends of the pair of side parts 22a is set slightly greater than the front-to-back width of the second semiconductor chip 5. On the other hand, the front-to-back distance between the pair of bottom parts 22b is set smaller than the front-to-back width of the second semiconductor chip 5. The second semiconductor chip 5 is fixed to the side part 22a and the bottom part 22b via the bonding material 13. As shown in FIG. 9, the left end of the second semiconductor chip 5 is fixed along the left end of the bottom part 22b. It should be noted that the second semiconductor chip 5 may be fixed only to the bottom part 22b. Furthermore, the second semiconductor chip 5 may be fixed so that its left end protrudes further left than the left end of the bottom part 22b.

Next, the manufacturing method of the semiconductor device 200 will be described. Incidentally, the manufacturing method in Embodiment 1 differs mainly in the lead frame preparation process (Step S1), and this point will be explained. As shown in FIG. 10, the molding recess 19 of the first mold 17, is composed of a pair of concave structures 23 arranged in the front-to-back direction. On the upper surface of each concave structure 23, an inclined surface and a vertical flat surface with respect to the up-down direction corresponding to the side part 22a and the bottom part 22b of the support portion 22 are formed. The molded protrusion 20 of the second mold 18 has a convex structure 24 placed in a position facing the concave structure 23 of the first mold 17. On the bottom surface of the convex structure 24, an inclined surface and a vertical flat surface with respect to the up-bottom direction corresponding to the side part 22a and the bottom part 22b of the support portion 22. Between the pair of flat surfaces on the bottom surface of the convex structure 24, a cut-out portion 24a protruding downward from the flat surface is formed. In the above lead frame preparation process (Step S1), parts other than the pair of support portions 22 of the original plate 15 are punched out by the molded protrusions 20 advancing below the upper surface of the concave structure 23 of the molded recess 19, thereby forming the pair of support portions 22. In the above-mentioned mounting process (Step S2), bonding material 13 is applied not only to the bottom part 22b of the support portion 22 but also to the side part 22a which inclines upward as it moves away from the bottom part 22b, and the second semiconductor chip 5 is mounted. Additionally, the bonding material 13 may be applied only to the bottom surface 22b, and when mounting the second semiconductor chip 5, the bonding material 13 may be spread out to interpose the bonding material 13 between the side surface 22a and the second semiconductor chip 5.

As described above, the pair of support portions 22 are spaced apart from each other in the front-back direction. As a result, compared to when a pair of support portions 22 is connected in the front-back direction, the bottom part 22b can be provided on the lower side. Therefore, the physical distance between the first semiconductor chip 4 and the second semiconductor chip 5 can be reduced. Additionally, because the side part 22a inclines upwards as it moves away from the bottom part 22b, it becomes easier to apply the bonding material 13 to the side part 22a, thereby allowing for the enhancement of the bonding strength between the second semiconductor chip 5 and the recess 21.

### Embodiment 3

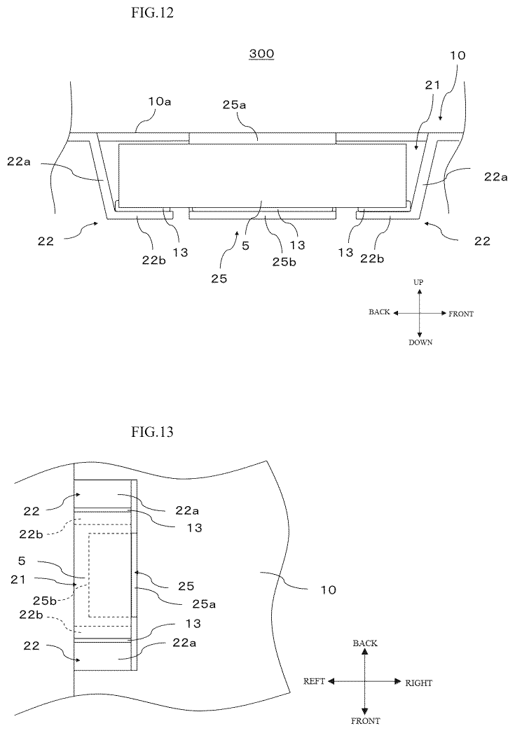

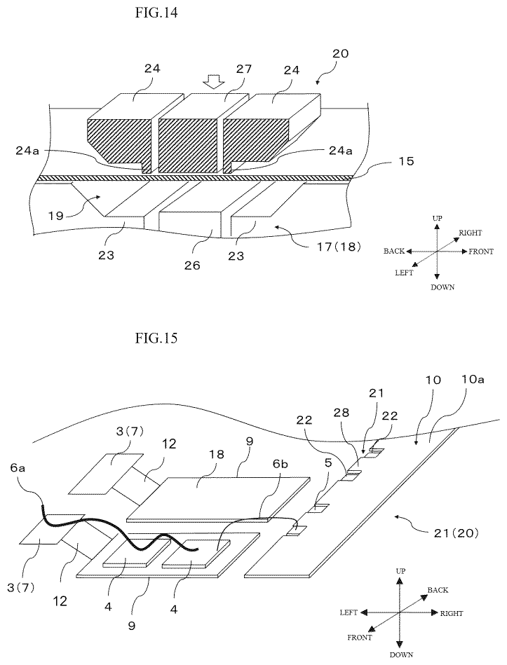

FIG. 11 is a perspective view showing the main part in the semiconductor device 300 according to Embodiment 3. FIG. 12 is a front view of the recess 21 in the second frame portion 10 of the semiconductor device 300 according to Embodiment 3. FIG. 13 is a plan view of the recess 21 in the second frame portion 10 of the semiconductor device 300 according to Embodiment 3. FIG. 14 is a perspective view illustrating the process of manufacturing the lead frame 7 of the semiconductor device 300 according to Embodiment 3. In the semiconductor device 300 related to Embodiment 3, the components identical or similar to those in the semiconductor device 200 related to Embodiment 2 are assigned the same reference numerals. The explanation below will mainly focus on the aspects differing from Embodiment 2.

As shown in FIGS. 11, 12, and 13, the recess 21 is equipped with a positioning part 25 on the side opposite to the open edge. The positioning part 25 is located between the pair of support portions 22 in the front-back direction, spaced apart from the pair of support portions 22. The positioning part 25 consists of a side surface 25a which slopes downward to the left from the right edge of the recess 21, and a bottom surface 25b which extends from the lower end of the side surface 25a bent to the left. The bottom surface 25b is positioned at the same height as the bottom surface 22b of the support portion 22. The left side of the bottom part 25b of the positioning part 25 is located to the right of the left side of the bottom part 22b of the support portion 22. The distance in the left-right direction from the right side of the upper surface of the bottom part 25b to the left side of the bottom part 22b is the same as the width of the second semiconductor chip 5 in the left-right direction. The second semiconductor chip 5 is placed on the bottom part 22b of the pair of support portions 22 and the bottom part 25b of the positioning part 25, and is fixed in the recess 21 while being in contact with the bent portion of the positioning part 25. The left end of the second semiconductor chip 5 is fixed along the left end of the bottom part 22b of the support portion 22.

Next, the manufacturing method of the semiconductor device 300 will be explained. Furthermore, the manufacturing method in Embodiment 2 differs in terms of the lead frame preparation process (Step S1), and this point will be explained in focus. As shown in FIG. 14, the molded recess 19 of the first mold 17 consists of a pair of concave structures 23, arranged in the front-to-back direction, and an intermediate concave structure 26 provided between the concave structures 23. On the upper surface of each concave structure 23, an inclined surface and a flat surface perpendicular to the up-down direction corresponding to the side part 22a and the bottom part 22b of the support portion 22 are formed. On the upper surface of the intermediate concave structure 26, an inclined surface and a flat surface perpendicular to the up-down direction corresponding to the side part 25a and the bottom part 25b of the positioning part 25 are formed. The molded protrusion 20 of the second mold 18 consists of three convex structures 24, 27 arranged in the front-to-back direction. In the position corresponding to concave structures 23 of the first mold 17, convex structure 24 is provided. On the lower surface of the convex structure 24, an inclined surface and a flat surface perpendicular to the up-down direction are formed, corresponding to the side surface 22a and the bottom surface 22b of the supporting part 22, respectively. On the lower surface of the convex structure 24, a cut-out portion 24a is provided, which protrudes further downward than the flat surface perpendicular to the up-down direction in the inner end of the front-back direction and the right end. Each cut-out portion 24a is situated in a gap between the concave structure 23 of the molded recess 19 and the intermediate concave structure 26 in the front-back direction. The lower surface corresponding to the upper surface of the intermediate concave structure 26 is formed on the intermediate convex structure 27. Additionally, the left end of the intermediate convex structure 27 protrudes downward to the same extent as the cut-out portion 24a. In the above lead frame preparation process (Step S1), by having the molded protrusion 20 advance downward towards the molded recess 19, parts other than the pair of supporting sections 22 and the positioning part 25 of the original plate 15 are punched out, thereby forming the pair of supporting sections 22 and the positioning part 25.

As mentioned above, the second semiconductor chip 5 is in contact with the positioning part 25 provided at the right end of the recess 21. This prevents the second semiconductor chip 5 from shifting away from the first frame portion 9. Consequently, it can be suppressed that the length of the wire 6b connecting the first semiconductor chip 4 and the second semiconductor chip 5 becomes longer.

### Embodiment 4

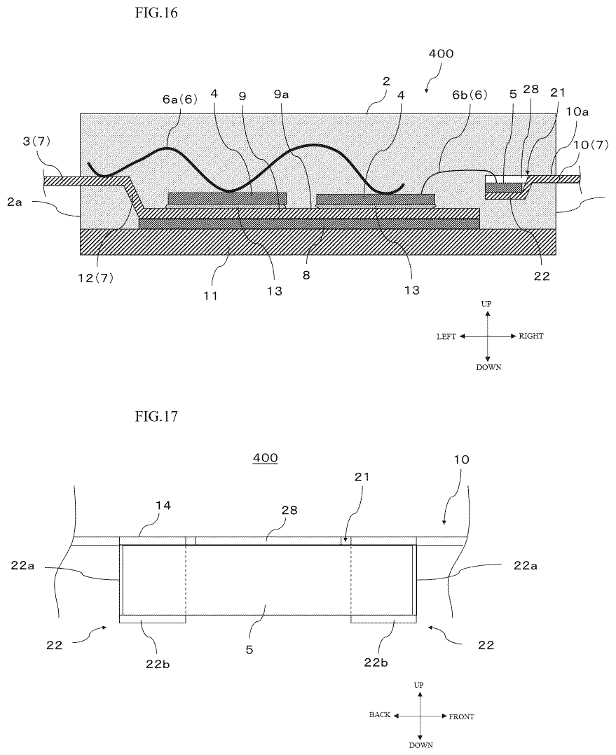

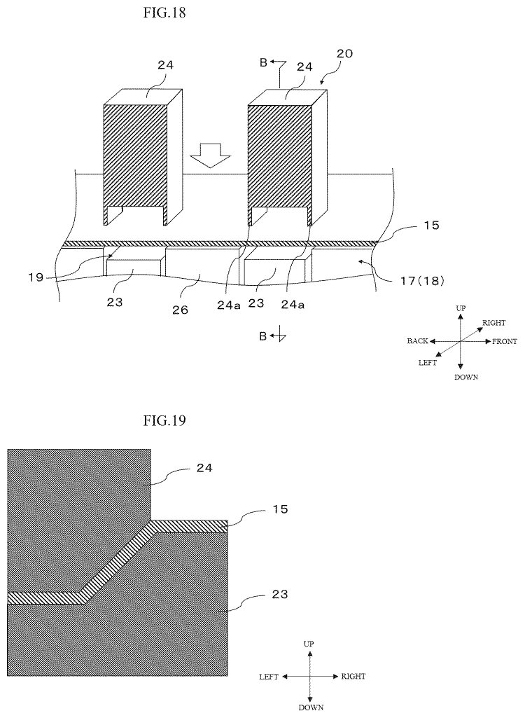

FIG. 15 is a perspective view showing the main part inside the semiconductor device 400 according to Embodiment 4. FIG. 16 is a cross-sectional view of the semiconductor device 400 according to Embodiment 4. FIG. 17 is a front view of the recess 21 in the second frame portion 10 of the semiconductor device 400 according to Embodiment 4. FIG. 18 is a perspective view showing a process for manufacturing the lead frame 7 of the semiconductor device 400 according to Embodiment 4. FIG. 19 is a cross-sectional view along line B-B in FIG. 18, showing a process for manufacturing the lead frame 7 of the semiconductor device 400 according to Embodiment 4. Hereinafter, in the semiconductor device 400 related to Embodiment 4, the same or similar portions to the semiconductor device 200 related to Embodiment 2 will be assigned the same reference numerals. The focus will be on explaining the differences from Embodiment 2.

As shown in FIGS. 15, 16, and 17, the recess 21 is provided with a pair of support portions 22, which are spaced apart from each other in the front-back direction, and a recess upper part 28 positioned between both support portions 22. The pair of support portions 22 are provided at both ends, in the front-back direction, of the right side of the recess 21. Each support portion 22 is formed by bending a rectangular plate part. Each support portion 22 has a side part 22a inclined downward from the front and back end portions of the right edge of the recessed portion 21, extending to the left, and a bottom part 22b extending to the left from the lower end of the side part 22a. Therefore, the side part 22a is inclined upwards as it moves away from the bottom part 22b. The recess upper part 28 is arranged spaced apart from the pair of support portions 22. The recess upper part 28 is a rectangular plate that is long in the front-back direction and extends to the left from the central part in the front-back direction of the right edge of the recess 21. The distance in the up-down direction between the recess upper part 28 and the bottom part 22b of the pair of support portions 22 is set to be slightly larger than the dimension in the up-down direction of the second semiconductor chip 5. The second semiconductor chip 5 is fixed by being sandwiched vertically between the recess upper part 28 and the bottom surface 22b of the support portion 22, with the left edge of the second semiconductor chip 5 positioned along the left side of the recess 21. The second semiconductor chip 5 is fixed in the recess 21 without using any bonding material. The entire second semiconductor chip 5 is housed within the recessed portion 21, with the upper surface of the second semiconductor chip 5 positioned below the recess upper part 28. The wire 6b that connects the first semiconductor chip 4 and the second semiconductor chip 5 is connected to the second semiconductor chip 5 in a region of its upper surface other than the recess upper part 28. FIGS. 15 and 16 show the state where the wire 6b is connected to the front area of the recess upper part 28on the upper surface of the second semiconductor chip 5.

Next, the method for manufacturing the semiconductor device 400 will be described. Notably, in Embodiment 2, the manufacturing method differs in the lead frame preparation process and in the step of mounting the second semiconductor chip 5, so these points will be the focus of explanation. As shown in FIG. 18 and FIG. 19, the molded recess 19 of the first mold 17 is composed of a pair of concave structures 23 aligned in the front-back direction and an intermediate concave structure 26 provided between the pair of concave structures 23. The upper surface of the concave structure 23 is positioned lower than the intermediate concave structure 26. On the upper surface of each concave structure 23, there are formed an inclined surface and a flat surface that are vertical to the up-down direction corresponding to the side part 22a and the bottom part 22b of the support portion 22. The molded protrusion 20 of the second mold 18 is composed of a pair of convex structures 24 arranged in the front-back direction. In the position corresponding to the concave structure 23 of the first mold 17, the convex structure 24 is provided. At the lower surface of the convex structure 24, an inclined surface and a flat surface perpendicular to the up-down direction, corresponding respectively to the side part 22a and the bottom part 22b of the support portion 22, are formed. At both the front and back ends of the lower surface of the convex structure 24, cut-out portion 24a protruding downwards more than other parts of the lower surface are provided. In the punching process of the lead frame preparation step (Step S1) mentioned above, the convex structure 24 bends the original plate 15 to form the support portion 22 by advancing the molded protrusion 20 below the three parts of the molded recess 19, and the recess upper part 28 is formed by leaving the part between both support portions 22 of the original plate 15 unprocessed. In the above semiconductor device mounting process (step S2), the second semiconductor chip 5 is inserted from the left side of the recess 21 between the recess upper part 28 and the bottom part 22b of the support portion 22, and the second semiconductor chip 5 is fixed by being clamped from above and below by the recess upper part 28 and the bottom part 22b.

As described above, the second semiconductor chip 5 is fixed in the recess 21 without using a bonding material, by being sandwiched and held between the bottom part 22b of the support 22 and the recess upper part 28. This eliminates the need for bonding materials, which in turn removes the necessity for the heating process required for curing the bonding material. Therefore, it is possible to reduce the manufacturing steps of the semiconductor device 400.

The preferred embodiment has been described in detail above, but it is not limited to the above-described embodiment. Various modifications and substitutions can be made without departing from the scope outlined in the claims.

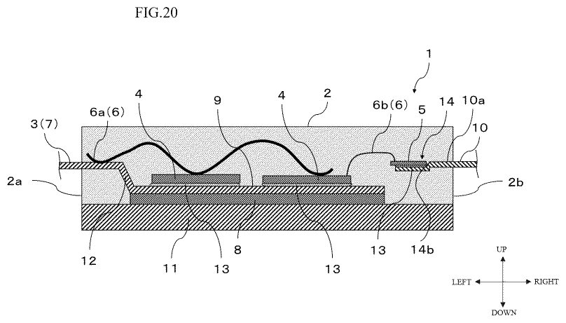

FIG. 20 is a diagram showing a modification example of Embodiment 1. The second semiconductor chip 5 may be fixed in the recess 14 in a state where it protrudes to the left of the left end of the recess 14, while maintaining an insulation distance from the first semiconductor chip 4. This further allows for shortening the length of the wire 6b. Additionally, in Embodiments 2 to 4, the second semiconductor chip 5 may be fixed in the recess 21 in a state where it protrudes to the left of the left end of the recess 21. Furthermore, when the second semiconductor chip 5 is fixed in a protruding state as described above, it is preferable that the side part 14b of the recess 14 or the side part 22a of the support portion 22 is inclined from the standpoint of junction strength with the second semiconductor chip 5. FIG. 20 shows the form in which the side part 14b of the recess 14 is inclined. Additionally, the recess 14 may be provided with a side part that rises upward around its entire perimeter.

In Embodiments 2 to 4, an example has been shown where two support portions 22 are provided, but this is not limited to two, and there can be three or more.

In the aforementioned embodiment, the first frame portion 9 and the second frame portion 10 are provided in a single lead frame 7, but the first frame portion 9 and the second frame portion 10 may be provided separately. For example, the first frame portion 9 may be made of an insulating substrate, and the second frame portion 10 may be made of a metallic material.

Below, various aspects of this disclosure will be summarized in an appendix.

### (Appendix 1)

A semiconductor device comprising:
a first semiconductor chip,
a second semiconductor chip connected to the first semiconductor chip,
a wire connecting the first semiconductor chip and second semiconductor chip,
a first frame portion on which the first semiconductor chip is mounted,
a second frame portion positioned above the first frame portion and apart in a left-right direction from the first frame portion and on which the second semiconductor chip is mounted, and
a sealing member sealing the first semiconductor chip, the second semiconductor chip, the first frame portion, the second frame portion, and the wire, wherein
a recess recessed downward is formed on an upper surface of the second frame portion,
the recess is positioned above the first frame portion, and
the second semiconductor chip is fixed in the recess.

### (Appendix 2)

The semiconductor device according to appendix 1, wherein the recess is located on the edge of the upper surface of the second frame portion facing the first frame portion and has an open edge toward the first frame portion.

### (Appendix 3)

The semiconductor device according to appendix 2, wherein the second semiconductor chip is fixed in the recess such that its end is aligned with the open edge of the recess or protrudes beyond the open edge of the recess toward the first frame portion.

### (Appendix 4)

The semiconductor device according to any one of appendixes 1 to 3, wherein the recess includes a bottom part and a side part inclined upward as it move away from the bottom part, and
the second semiconductor chip is fixed to the bottom part and the side part via a bonding material.

### (Appendix 5)

The semiconductor device according to any one of appendixes 2 to 4, wherein the recess includes a plurality of support portions spaced apart in a front-back direction intersecting with the left-right direction and supporting the second semiconductor chip,
each of the support portions includes a bottom part and a side part extending upward from the bottom part and connected to a peripheral portion of the recess in the second frame portion, and
the second semiconductor chip is fixed to the plurality of support portions.

### (Appendix 6)

The semiconductor device according to appendix 5, wherein the recess includes a positioning part opposite the open edge of the recess in the left-right direction, and
the second semiconductor chip is in contact with the positioning part.

### (Appendix 7)

The semiconductor device according to appendix 5, wherein the recess includes an upper part located above the bottom part, and
the second semiconductor chip is sandwiched and fixed between the bottom part and the upper part.

### (Appendix 8)

A method for manufacturing a semiconductor device comprising:
preparing a first frame portion and a second frame portion positioned above the first frame portion and apart in a left-right direction from the first frame portion,
mounting a first semiconductor chip on the first frame portion and a second semiconductor chip on the second frame portion,
connecting the first semiconductor chip and the second semiconductor chip with a wire, and
sealing the first semiconductor chip, the second semiconductor chip, the first frame portion, the second frame portion, and the wire with a sealing member, wherein
in the preparation,
a first mold having a molding recess, a second mold arranged opposite the molding recess and movable toward and away from the first mold, having a molding protrusion corresponding to the molding recess, and an original plate for the second frame potion are prepared,
the original plate is placed in an area of the first mold including the molding recess,
the second mold advances toward the first mold and punches out the original plate to form the second frame potion, and a recess is formed in the formed second frame potion that is recessed downward and located above the first frame portion, and
in the mounting, the second semiconductor chip is fixed in the recess.

According to the semiconductor device and the method for manufacturing the semiconductor device related to the disclosure, it is possible to suppress the deformation of the wire while maintaining the insulating distance between semiconductor chips in the semiconductor device sealed with the sealing member.

Obviously many modifications and variations of the present disclosure are possible in the light of the above teachings. It is therefore to be understood that within the scope of the appended claims the disclosure may be practiced otherwise than as specifically described.

The entire disclosure of a Japanese Patent Application No. 2024-204450, filed on Nov. 25, 2025 including specification, claims, drawings and summary, on which the Convention priority of the present application is based, are incorporated herein by reference in its entirety.

1. A semiconductor device comprising:
a first semiconductor chip,
a second semiconductor chip connected to the first semiconductor chip,
a wire connecting the first semiconductor chip and second semiconductor chip,
a first frame portion on which the first semiconductor chip is mounted,
a second frame portion positioned above the first frame portion and apart in a left-right direction from the first frame portion and on which the second semiconductor chip is mounted, and
a sealing member sealing the first semiconductor chip, the second semiconductor chip, the first frame portion, the second frame portion, and the wire, wherein
a recess recessed downward is formed on an upper surface of the second frame portion,
the recess is positioned above the first frame portion, and
the second semiconductor chip is fixed in the recess.

2. The semiconductor device according to claim 1, wherein the recess is located on the edge of the upper surface of the second frame portion facing the first frame portion and has an open edge toward the first frame portion.

3. The semiconductor device according to claim 2, wherein the second semiconductor chip is fixed in the recess such that its end is aligned with the open edge of the recess or protrudes beyond the open edge of the recess toward the first frame portion.

4. The semiconductor device according to claim 1, wherein the recess includes a bottom part and a side part inclined upward as it move away from the bottom part, and
the second semiconductor chip is fixed to the bottom part and the side part via a bonding material.

5. The semiconductor device according to claim 2, wherein the recess includes a plurality of support portions spaced apart in a front-back direction intersecting with the left-right direction and supporting the second semiconductor chip,
each of the support portions includes a bottom part and a side part extending upward from the bottom part and connected to a peripheral portion of the recess in the second frame portion, and
the second semiconductor chip is fixed to the plurality of support portions.

6. The semiconductor device according to claim 5, wherein the recess includes a positioning part opposite the open edge of the recess in the left-right direction, and
the second semiconductor chip is in contact with the positioning part.

7. The semiconductor device according to claim 5, wherein the recess includes an upper part located above the bottom part, and
the second semiconductor chip is sandwiched and fixed between the bottom part and the upper part.

8. A method for manufacturing a semiconductor device comprising:
preparing a first frame portion and a second frame portion positioned above the first frame portion and apart in a left-right direction from the first frame portion,
mounting a first semiconductor chip on the first frame portion and a second semiconductor chip on the second frame portion,
connecting the first semiconductor chip and the second semiconductor chip with a wire, and
sealing the first semiconductor chip, the second semiconductor chip, the first frame portion, the second frame portion, and the wire with a sealing member, wherein
in the preparation,
a first mold having a molding recess, a second mold arranged opposite the molding recess and movable toward and away from the first mold, having a molding protrusion corresponding to the molding recess, and an original plate for the second frame potion are prepared,
the original plate is placed in an area of the first mold including the molding recess,
the second mold advances toward the first mold and punches out the original plate to form the second frame potion, and a recess is formed in the formed second frame potion that is recessed downward and located above the first frame portion, and
in the mounting, the second semiconductor chip is fixed in the recess.
